(19) United States
(12) Patent Application Publication
(10) Pub. No.: US 2010/0141089 A1
(43) Pub. Date: Jun. 10, 2010

(54) TRIGGER CIRCUIT AND TRIGGERING METHOD FOR A PIEZOELCTRIC ELEMENT

(76) Inventors: Joerg Schestag, Niefern-Oschelbronn (DE); Nils Draese, Stuttgart (DE)

Correspondence Address: KENYON & KENYON LLP, ONE BROADWAY, NEW YORK, NY, 10004, US

(21) Appl. No.: 12/449,901

(22) PCT Filed: Mar. 11, 2008
(86) PCT No.: PCT/EP2008/052883

§ 371 Date: Feb. 1, 2010

(30) Foreign Application Priority Data
Mar. 26, 2007 (DE) 10 2007 014 330.5

(51) Int. Cl. H01L 41/09

(52) U.S. Cl. 310/317

(57) ABSTRACT

A trigger circuit for a piezoelectric element for injecting fuel into a combustion chamber of an internal combustion engine includes: a voltage source which, at a first, second and third connection points, respectively, provides a low, medium and high electrical potential, the second connection point being developed for being coupled to a first electrode of the piezoelectric element; a charge switching element that connects a second electrode of the piezoelectric element to the third connection point of the voltage source; and a discharge switching element that connects the second electrode of the piezoelectric element to the first connection point of the voltage source.

### BACKGROUND OF THE INVENTION

1. Field of the Invention

The present invention relates to a trigger circuit and a triggering method for a piezoelectric element for injecting fuel into a combustion chamber in an internal combustion engine.

2. Description of Related Art

Triggering devices for piezoelectric elements are used in fuel injection systems of a motor vehicle, for example. The piezoelectric elements are used as actuators, the performance reliability of the fuel injection system being based on an accurate triggering of the actuators using a control current.

In published German patent document DE 10 2004 037 720, a control circuit for an actuator is described, a piezoelectric element being controlled that moves a valve needle of an injection valve, for example, in order to bring about a fuel injection into a combustion chamber of the internal combustion engine.

Published German patent document DE 10 2004 058 671 discloses a further electric circuit for triggering piezoelectric elements, particularly of a fuel injection system of a motor vehicle, which has series connections of piezoelectric elements and select transistors which are connected in parallel. The secondary side of a DC voltage transformer is connected via a diode to a buffer capacitor which provides an operating potential of up to 330 V DC voltage compared to a ground potential of the motor vehicle. The operating potential is able to be supplied to the anodes of the piezoelectric elements via switching transistors that are controllable by a clock pulse, one piezoelectric element being selected using select transistors. Two select transistors connected in series are provided in this instance, whose common connection point is coupled to an anode of the piezoelectric element that is to be controlled, and of which one is provided for charging and one for discharging the anode of the piezoelectric element, respectively. Ground potential is present at the cathode, in this instance.

Now, if one of the piezoelectric elements is charged via the switching transistor provided for charging, the piezoelectric element acts on the valve needle of an injection valve, and fuel is injected into the combustion chamber of the internal combustion engine. In response to the subsequent discharge via the switching transistor provided for the discharge, the piezoelectric element guides the valve needle back, so that the valve closes again.

In order to be able to perform the injection according to a desired injection profile, at as accurately defined a point in time as possible, using precise metering, it would be desirable to be able to open and close the valve by the piezoelectric element, using as great a lift as possible, as rapidly as possible. Therefore, in known trigger circuits, in order to charge the anode of the piezoelectric element, as high as possible an operating potential is used, in order thus to generate a triggering signal having as great as possible an amplitude and a great slope steepness.

However, in this connection, the maximum operating potential to be used is limited by a maximum voltage endurance of the piezoelectric element, since by applying voltages above this value, the destruction of the piezoelectric element would occur. Furthermore, using higher voltages requires greater expenditure for wiring and plug connections, and in addition may lead to a deterioration of the electromagnetic tolerance of the trigger circuit, so that additional expenditure is created for screening at the trigger circuit itself, and also at other electronic devices in the vehicle.

Therefore, an object of the present invention to create a trigger circuit which achieves an increased lift and greater closing and opening speed of the valve needle, and thereby makes it possible to design the injection profile variably, according to requirements, having a greater variation breadth, without having to raise the operating potential above a maximum established value.

### BRIEF SUMMARY OF THE INVENTION

One essential idea of the present invention is not only to charge and discharge the piezoelectric element in a cyclical unipolar manner, but rather, to invert the polarity of the voltage to be applied by the trigger circuit to the electrodes of the piezoelectric element, during one injection cycle.

By doing this, the advantage comes about, for one thing, that the absolute value of the difference between the voltage values, subject to their signs, which are able to be applied in both directions to the piezoelectric element, respectively, during an injection process, becomes greater. This increases the attainable mechanical lift of the injector valve, without the necessity of increasing the absolute value of the voltage applied to the piezoelectric element at any given time.

An additional important advantage is that the slope steepness of the trigger current signal is increased, which makes possible a more rapid opening and closing of the valve, and, along with that, a more precise establishment of the point in time of the injection. The greater slope steepness further permits regulating with high precision the respective voltage applied to the piezoelectric element, and along with that, the mechanical excursion of the element and the quantity of the injected fuel.

According to one general point of view of the present invention, a trigger circuit is provided for a piezoelectric element, for injecting fuel into a combustion chamber of an internal combustion engine, having a voltage source which, at a first, second and third connection point, respectively, provides a low, medium and high electrical potential, the second connection point being developed for coupling to a first electrode of the piezoelectric element, a charge switching element that connects a second electrode of the piezoelectric element to the third connection point of the voltage source, and a discharge switching element that connects the second electrode of the piezoelectric element to the first connection point of the voltage source.

Consequently, by suitable control of the switching elements during operation, the trigger circuit makes it possible optionally to connect the second electrode to the lower or the higher potential, while the first electrode is coupled by coupling to the medium potential.

According to one preferred refinement, the first connection point of the voltage source is developed for coupling to a ground potential of the internal combustion engine. This has the advantage that the discharge switching element is at a lower potential with respect to ground, and is thus able to be formed by a transistor that is directly controlled by an integrated circuit, without interconnection of a driver stage having voltage endurance. The voltage source is preferably developed for being fed from a DC network, the second and third connection points having the same polarity with respect to the mass potential as the DC network. In this way, for example, in a vehicle electrical system of a motor vehicle having positive polarity with respect to ground, the triggering of the piezoelectric element is able to take place exclusively using potentials that are also positive with respect to ground, whereby it becomes possible to allow these potentials to be controlled and regulated by such switching circuits as are solely fed by DC voltage, taken from the vehicle electrical system, having positive polarity with respect to ground. In the same way, for example, in a vehicle electrical system having negative polarity with respect to ground, the triggering of the piezoelectric element is able to take place exclusively using potentials that are also negative with respect to ground, whereby it becomes possible to allow these potentials to be controlled and regulated by such switching circuits as are solely fed by DC voltage, taken from the vehicle electrical system, having negative polarity with respect to ground.

At a piezoelectric element, in one of the possible polarity directions, typically a greater maximum voltage may be applied than in the respectively opposite direction. According to one preferred further development of the trigger circuit according to the present invention, a voltage between the higher and the medium potential has a greater absolute value than a voltage between the medium and the lower potential. This has the advantage that the piezoelectric element is able to be operated so that the center potential and, as a result, the first electrode of the piezoelectric element as well as, overall, as great a part as possible of the trigger circuit get to be at as low as possible a potential with respect to ground. This reduces the circuit and insulation expenditures, whereas the electromagnetic compatibility is improved.

According to another preferred refinement, the voltage source includes a DC converter, in particular, a reverse converter, or a single-ended forward converter. The potentials required may thereby be obtained, at high efficiency and low circuit expenditure, from an already present DC network, such as the vehicle electrical system of a motor vehicle. The reverse converter is particularly advantageous because of its simple circuit layout and small space requirement, while a single-ended forward converter is superior at output performances at higher requirements, for instance, in applications for larger internal combustion engines.

The DC converter preferably includes a transformer having a primary winding and a first and a second secondary winding, a primary circuit as well as a first and second secondary circuit being provided. The primary circuit includes a primary circuit switching element and the primary winding of the transformer. The secondary circuit includes a first rectifier element, a first capacitor and the first secondary winding, while the second secondary circuit includes a second rectifier element, a second capacitor and the second secondary winding of the transformer. This is particularly advantageous since both the voltage between the lower and the medium potential and the voltage between the medium and the higher potential are able to be generated by a DC converter having a single primary circuit, which reduces the circuit expenditure. The first and the second capacitor are preferably connected in series, the terminal ends of the capacitors that are connected to each other being coupled to the second connection point of the voltage source. The other terminal ends of the first and second capacitors, respectively, are coupled to the first or the third connection point of the voltage source.

The voltage source preferably includes a regulating unit for regulating a total voltage between the first and third connection point, which is connected to the first and third connection point of the voltage source and which cyclically activates the primary circuit switching element as a function of the total voltage. This is advantageous because, in that manner, the total voltage that is decisive for the overall lift of the piezoelectric element is able to be regulated over the two secondary circuits. The use of only one single regulating unit limits the circuit expenditure, particularly if, by the use of a voltage divider, the total voltage is lowered to a value the regulating unit is able to tolerate. The regulating unit preferably includes a characteristics curve, which determines a relationship between the total voltage (as an output voltage of the voltage source, that is to be regulated) and the duration of activation of the primary circuit switching element. The regulating unit is thus able to be set to the special load requirements in the operation of the internal combustion engine, using the characteristics line. In this context, the characteristics line establishes a triple relationship between the network voltage (as input voltage feeding the voltage source), the total voltage (as the output voltage of the voltage source, that is to be regulated) and the duration of activation of the primary circuit switching element, which makes it possible to make the voltage source, and thus also the operation of the internal combustion engine, robust to a great degree with respect to the fluctuations of the network voltage.

According to the triggering method of the present invention, for triggering a piezoelectric element for the injection of fuel into a combustion chamber of an internal combustion engine, first of all a ground potential and a predetermined charge potential are provided. A first electrode of the piezoelectric element is established at a predetermined center potential between the ground potential and the charge potential. The charge potential is now applied to a second electrode of the piezoelectric element. In further steps, the second electrode is disconnected from the charge potential, and the ground potential is applied to the second electrode. In this manner, the piezoelectric element is discharged by a discharge current having an especially great slope steepness, since, at the moment the ground potential is applied to the second electrode, the first electrode is at the center potential, and thus a voltage is applied to the piezoelectric element which is of reversed polarity compared to the voltage with which the element was charged. The two voltages therefore act together in generating the discharge current.

### BRIEF DESCRIPTION OF SEVERAL VIEWS OF THE DRAWING

FIG. 1 shows a schematic block diagram of a trigger circuit for a piezoelectric element for injecting fuel into a combustion chamber of an internal combustion engine, according to an example embodiment of the present invention.

FIG. 2 shows a circuit diagram of a voltage source for the trigger circuit for a piezoelectric element shown in FIG. 1.

### DETAILED DESCRIPTION OF THE INVENTION

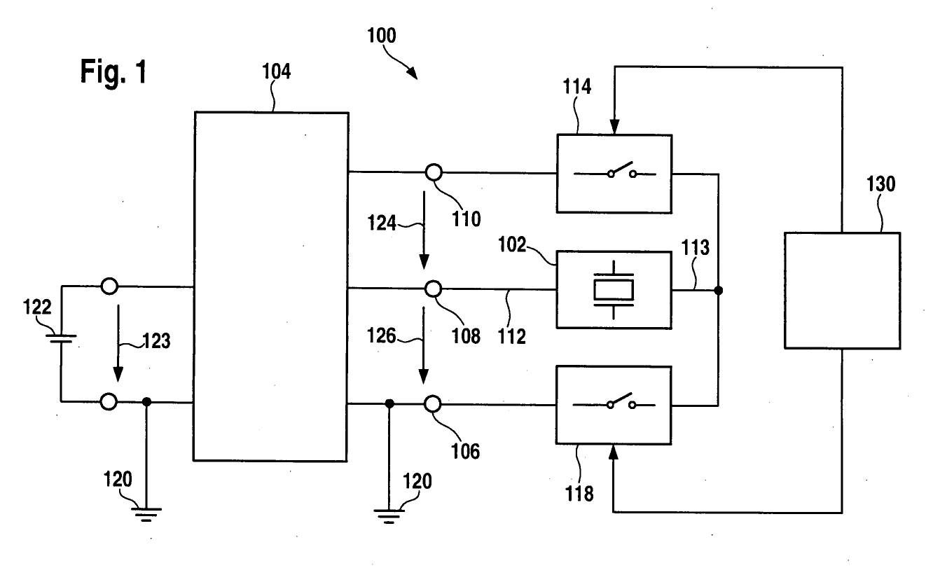

FIG. 1 shows a schematic block diagram of a trigger circuit 100 for a piezoelectric element 102 for injecting fuel into a combustion chamber of an internal combustion engine, for instance, an internal combustion engine that drives a motor vehicle.

Trigger circuit 100 includes a voltage source 104 that is fed from a DC network 122, which makes available a network voltage 123 of 12 V DC, for example. The negative pole of DC voltage network 122 is connected to a ground potential 120 of the motor vehicle, including the internal combustion engine, so that DC voltage network 122 provides a positive potential of 12 V with respect to ground potential 120 at its other pole. Motor vehicles typically have such a DC voltage network 122, or the like, as the vehicle electrical system, so that the trigger circuit shown is able to be operated from the regularly present vehicle electrical system of a motor vehicle.

Voltage source 104, on its output side, has three connection points 106, 108, 110, at which it provides two voltages 124, 126. A first connection point 106 is at ground potential 120, in this instance. A DC voltage 124 is provided between a second connection point 108 and a third connection point 110 as charging voltage, which represents the upper limit of a voltage with which piezoelectric element 102 is to be charged during operation. The charging voltage 124 has an absolute amount of 220 V, for example. Trigger circuit 100 may alternatively include additional regulating units (not shown), which monitor and limit the voltage applied to the piezoelectric element during operation. In this case, charging voltage 124 may have a greater amount than the voltage to be applied as a maximum to the piezoelectric element, for example, 240 to 250 V.

Between the first and the second 108 connection point that are at ground potential 120, voltage source 104 sets up an additional DC voltage 126 as discharging voltage, which is to be applied during operation to the piezoelectric element 102, so as to discharge it and, if necessary, to charge it up to a maximum to the absolute amount of discharging voltage 126 at reversed polarity. The charging voltage 126 has an absolute amount of 45 V, for example. If trigger circuit 100, as was mentioned above, includes additional regulating devices (not shown), which monitor and limit the voltage applied to the piezoelectric element during operation, the reverse charging of piezoelectric element 102 during operation may also take place only up to a smaller maximum absolute voltage amount, or even be omitted altogether.

Discharging voltage 126, provided between first connection point 106 and second connection point 108, has the same polarity as charging voltage 124, provided between second connection point 108 and third connection point 110, so that the two add up to a total voltage. In addition, charging voltage 124 and discharging voltage 126 have the same polarity as DC current network 122. Accordingly, voltage source 104 at its first connection point 106, its second connection point 108 and its third connection point 110 in each case, in relationship to ground potential 120, provides a lower potential (that is, identical to ground potential 120), a medium potential (of +45 V with respect to ground 120 in the present example) and a higher potential (of +45 V +220 V=+265 V in the present example), the terms “low”, “medium” and “high” referring to the respective absolute voltage amount with respect to ground potential 120, so that, in an alternative specific embodiment of the present invention they would also be valid having the reversal of all the polarities.

Piezoelectric element 102 is coupled to second connection 108 of voltage source 104, using a first electrode 112. Therefore, using the voltages given as an example, first electrode 112 in operation is constantly at the medium potential of +45 V. Second electrode 113 of piezoelectric element 102 is connected to third connection point 110 and first connection point 106 via a charging switching element 114 and a discharging switching element 118 that are each switchable. Switching elements 114, 118 are connected to a clock signal unit 130, which controls switching elements 114, 118 via a clock signal in a coordinated manner.

During operation, voltage source 104, at its connection points 106, 108, 110 first provides the lower, medium and higher potential respectively. Consequently, the medium potential of +45 V is present at the first electrode of piezoelectric element 102. During the course of a clock cycle of clock signal unit 130, clock signal unit 130 sends a signal to charging switching unit 114, so that the latter connects in a conducting manner the connection between second electrode 113 of piezoelectric element 102 and third connection point 110 of voltage source 104. By doing this, the charging voltage 124 of 220 V is applied to piezoelectric element 102. After the completed charge, second electrode 113 is at a potential of +265 V. In this case, clock signal unit 130 sends a clock signal to charge switching unit 114, which breaks the connection again between second electrode 113 of piezoelectric element 102 and third connection point 110 of voltage source 104. In order to limit the charging current flowing through piezoelectric element 102 during the charging process, for instance, to avoid damage, it may further be provided that clock signal unit 130 allows charge switching unit 114 to interrupt the charge current one or more times intermediately, before piezoelectric element 102 is charged to the full value of the voltage desired. For example, clock signal unit 130 is able to trigger the interruption when the charge current exceeds a predetermined maximum value, in order then, in response to falling below a further, predetermined threshold value, or even after a specified time has passed, again to send a clock signal to charge switching unit 114, which prompts it to continue the charging process.

During the course of a clock cycle, if piezoelectric element 102 is to be discharged, clock signal unit 130 sends a signal to discharging switching unit 118, so that the latter connects in a conducting manner the connection between second electrode 113 of piezoelectric element 102 and first connection point 106 of voltage source 104. This applies the discharging voltage 126 of 45 V to piezoelectric element 102, in fact, in reverse to the polarity of the voltage of 220 V, at which level piezoelectric element 102 is still charged at this point. The two voltages add up in their effect, so that a high discharge current flows through piezoelectric element 102, while the potential of second electrode 113 drops off. If the potential of second electrode 113 drops off to the medium potential of voltage source 104, the discharge current continues to flow because of the effect of discharge voltage 126, until piezoelectric element 102 has been charged to a voltage of 45 V at reverse polarity. If necessary, clock signal unit 130 is able prematurely to interrupt the discharge or recharge process, for instance, as soon as a desired potential of second electrode 113 is achieved, which may be both higher and lower than the medium potential of voltage source 104, and is also able intermediately to interrupt once or more for the purpose of limiting the discharge and recharge current, as was described above for the charging process.

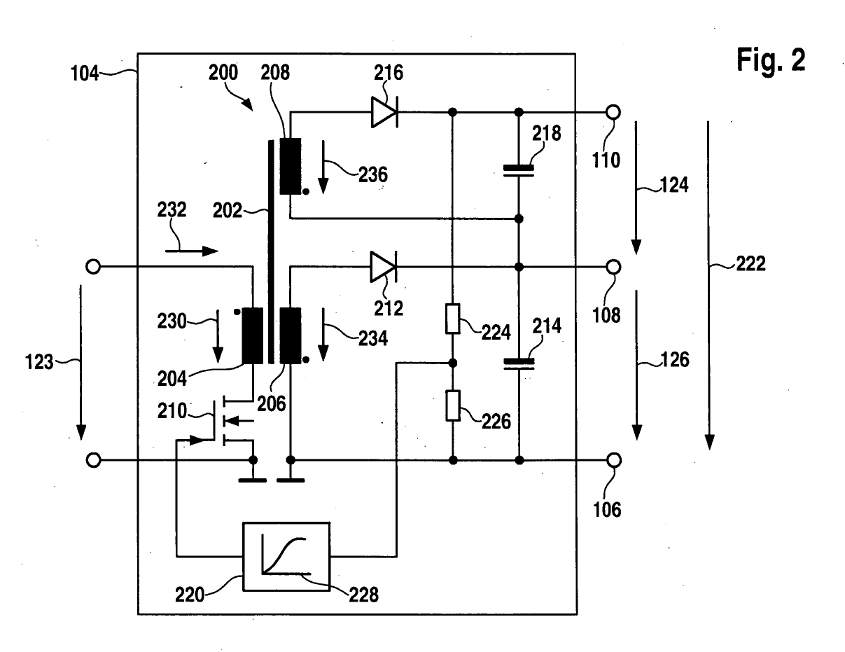

FIG. 2 shows an exemplary circuit diagram of a voltage source 104, of the kind that may be used as the trigger circuit for a piezoelectric element as in FIG. 1. Voltage source 104 includes a DC voltage transformer 200 that works according to the reverse converter principle. DC voltage transformer 200 includes a transformer 202 having a primary winding 204 and two secondary windings 206, 208.

Primary winding 204 forms a primary circuit, in common with a transistor 210, as a switching element that is controllable by a regulating unit 220, and the primary circuit is developed for connecting to network voltage 123 of the vehicle electrical system. First secondary winding 206, together with a first diode 212 and a first buffer capacitor 214, forms a first secondary circuit, while secondary winding 208, together with a second diode 216 and a second buffer capacitor 218 forms a second secondary circuit. The terminal end of first buffer capacitor 214 connected to first diode 212, and the terminal end of the second buffer capacitor not connected to the second diode 216 are connected to each other as well as to second connection point 108 of voltage source 104. The respectively other terminal ends of first buffer capacitor 214 and the second buffer capacitor are connected to first connection point 106 and third connection point 110 of voltage source 104. The two capacitors 214, 218 are thus connected in series.

In operation, the primary circuit is connected to network voltage 123 of the vehicle electrical system. Regulating unit 220 renders transistor 210 conducting, so that network voltage 123, that is present on the input side, is equal to voltage 230 that is present at primary winding 204, and primary current 232 rises linearly. In this phase, energy is stored in the core of transformer 202 via primary winding 204. Secondary windings 206, 208 are currentless in this phase, since diodes 212, 216 are blocking. Now, if transistor 210 is blocked by regulating unit 220, diodes 212, 216 become conducting, and the energy stored in the transformer core is given off on the secondary side to capacitors 214, 218. In this context, the stored energy is subdivided exactly in such a way that secondary voltages 234, 236, and thus output voltages 124, 126 subdivide corresponding to the winding ratio of secondary windings 206, 208. Output voltages 124, 126 add up to a total voltage 222, based on the series connection of capacitors 214, 216.

During the clock cycle, regulating unit 220 measures this voltage, that is present at the capacitors 214, 218 that are connected in series, and that is provided by voltage source 104 between its first connection point 106 and its third connection point 110, via voltage divider 224, 226, and compares the measured value internally to a stored threshold value. If the measured value is less than the threshold value, regulating unit 220 first renders transistor 210 conducting, and, after the passage of an activation period, non-conducting again. The activation time of transistor 210 is ascertained, in this instance, via a characteristics field 228, that is stored in regulating unit 220, which gives the optimum activation duration as a function of the voltage applied to primary winding 204 (that is, of network voltage 123 that is also available to regulating unit 220). In this context, the optimum duration of activation is the one at which the maximum possible energy is transmitted per clock cycle, without having transformer 202 reaching a saturation range. Characteristics field 228 is able to include still further characteristics lines, using which, for example, a run-up of the DC voltage transformer from the rest state is controlled.

1-10. (canceled)

11. A trigger circuit for a piezoelectric element for injecting fuel into a combustion chamber of an internal combustion engine, comprising:
a voltage source configured to provide a first electrical potential at a first connection point, a second electrical potential at a second connection point higher than the first electrical potential, and a third electrical potential at a third connection point higher than the second electrical potential, wherein the second connection point is configured for coupling to a first electrode of the piezoelectric element;
a charging switching element which connects a second electrode of the piezoelectric element to the third connection point of the voltage source; and
a discharging switching element which connects the second electrode of the piezoelectric element to the first connection point of the voltage source.

12. The trigger circuit as recited in claim 11, wherein the first connection point of the voltage source is configured for coupling to a ground potential of the internal combustion engine.

13. The trigger circuit as recited in claim 12, wherein the voltage source is fed from a DC network, and wherein the second connection point and the third connection point have the same polarity with respect to the ground potential as the DC network.

14. The trigger circuit as recited in claim 12, wherein a voltage difference between the third potential and the second potential has a greater absolute value than a voltage difference between the second potential and the first potential.

15. The trigger circuit as recited in claim 12, wherein the voltage source includes a DC voltage transformer.

16. The trigger circuit as recited in claim 15, wherein the DC voltage transformer includes:
a transformer device having a primary winding, a first secondary winding and a second secondary winding;
a primary circuit including a primary circuit switching element and the primary winding of the transformer device;
a first secondary circuit including a first rectifier element, a first capacitor and the first secondary winding of the transformer device; and
a second secondary circuit including a second rectifier element, a second capacitor and the second secondary winding of the transformer device.

17. The trigger circuit as recited in claim 16, wherein the first capacitor and the second capacitor are connected in series, and wherein terminal ends of the first and second capacitors that are connected to each other are coupled to the second connection point of the voltage source, and wherein remaining terminal ends of the first capacitor and the second capacitor not connected to each other are coupled to the first connection point and the third connection point of the voltage source, respectively.

18. The trigger circuit as recited in claim 17, wherein the voltage source includes a regulating unit for regulating a total voltage between the first connection point and the third connection point, and wherein the regulating unit cyclically activates the primary circuit switching element as a function of the total voltage between the first connection point and the third connection point.

19. The trigger circuit as recited in claim 18, wherein the regulating unit includes a characteristics field defining a relationship between the total voltage and a duration of activation of the primary circuit switching element.

20. A method for triggering a piezoelectric element for injecting fuel into a combustion chamber of an internal combustion engine, comprising:
providing a ground potential of the internal combustion engine and a predetermined operating potential;
establishing a first electrode of the piezoelectric element to have a predetermined medium potential between the ground potential and the operating potential;
applying the operating potential to a second electrode of the piezoelectric element;
disconnecting the second electrode from the operating potential; and
applying the ground potential to the second electrode.
